(19) United States
(12) Patent Application Publication
(10) Pub. No.: US 2004/0263358 A1
(43) Pub. Date: Dec. 30, 2004

(54) Portable unit for inputting signals to a peripheral unit, and use of such a unit

(76) Inventors: Fredrik Madsen, Stockholm (SE); Kurt Hognelid, Bromma (SE); Tomas Oquist, Upplands Vasby (SE); Magnus Schnurer, Bromma (SE); Jonas Backman, Danderyd (SE)

Correspondence Address: McCormick Paulding & Huber, CityPlace II, 185 Asylum Street, Hartford, CT, 06103, US

(21) Appl. No.: 10/489,454

(22) PCT Filed: Sep. 13, 2002
(86) PCT No.: PCT/SE02/01648

(30) Foreign Application Priority Data
Sep. 14, 2001 (SE) 0103055-0

(51) Int. Cl. H03M 11/00; H03K 17/94

(52) U.S. Cl. 341/20; 345/161; 345/163

(57) ABSTRACT

The invention concerns a portable unit comprising a hand attachment device, suited to be easily attachable to and removable from a first hand of a person using the device, and at least a first input member arranged on said device for inputting signals to a peripheral unit. The attachment device comprises a U-shaped portion, which thus has first and second at least relatively straight parts and a bent part connecting said first and second parts. The attachment device is designed to be attachable to said first hand such that the first part is located essentially on the back of the hand, the second part is located essentially on the front of the hand while the bent part extends from the back of the hand to the front of the hand in the area between the thumb and the index finger of said first hand. The invention also concerns the use of such a unit.

### BACKGROUND OF THE INVENTION

The present invention concerns a portable unit comprising a hand attachment device, suited to be easily attachable to and removable from a first hand of a person using the device, and at least a first input member arranged on said hand attachment device for inputting signals to a peripheral unit which is not positioned on said attachment device. The unit may for example be arranged to input control signals to a computer of some kind. The computer may be a personal computer, a TV-game, a personal digital computer or any other entity. The control signals may for example constitute signals to input alphanumerical information to the peripheral unit or to input other graphical entities or commands to control graphics on a monitor which forms part of the peripheral unit. It is also possible that the control signals are used for controlling a three-dimensional entity of the peripheral unit such as, for example, a computer controlled robot arm.

Such a portable unit is known from, for example, U.S. Pat. No. 5,832,296. This document describes a device that preferably is worn as a ring around a finger of a hand of a user. The device may fulfil the same function as a standard computer mouse (see column 7, lines 6-18). The device is designed to be operated by the thumb of the same hand on which the device is worn.

WO96/39679 discloses another example of such a portable unit.

GB 2305714 discloses a keyboard glove. The glove is worn on a hand of a user. The glove comprises sensors for generating input characters when a pressure is sensed by the different sensors.

The above devices are sometimes difficult to attach to a hand of a user. Furthermore, these devices are often not found to be particularly comfortable to use.

### SUMMARY OF THE INVENTION

An object of the present invention is to provide a portable unit of the kind described above, which is easy to attach and to remove from the hand. A further object is to provide such a unit that may be positioned on the hand such that it is comfortable and easy to use. Another object is to provide such a unit which is advantageous to use from an ergonomic point of view.

The above objects are achieved by a device according to the first paragraph above, wherein said attachment device comprises a U-shaped portion, which thus has first and second at least relatively straight parts and a bent part connecting said first and second parts, wherein said attachment device is designed to be attachable to said first hand such that the first part is located essentially on the back of the hand, the second part is located essentially on the front of the hand while the bent part extends from the back of the hand to the front of the hand in the area between the thumb and the index finger of said first hand.

Because of the design of the attachment device, the portable unit is easy to attach to a hand. Furthermore, since the unit is designed to be attached to the part of the hand mentioned above, the unit is comfortable and ergonomically advantageous to use and also leaves the fingers of the hand free to be used for other purposes than for operating the unit.

According to one preferred embodiment, said U-shaped portion is at least slightly twisted such that said first and second parts are not parallel to each other. The unit according to this embodiment may be securely attached to the hand and is comfortable to use. It should however be noted that according to another embodiment, said first and second parts are parallel to each other.

According to another preferred embodiment, at least a part of the area of said attachment device that will be in contact with said first hand when the attachment device is positioned as intended on said first hand has a form that at least substantially corresponds to the shape of the corresponding part of a normally built said first hand of a person using the device. Since the shape of the device corresponds to the shape of the hand, the device can be held to the hand without there being any need for any additional means for holding the device onto the hand. The area of said attachment device that will be in contact with said hand may also be provided with a surface that has a sufficiently high friction against the hand in order securely hold the device onto the hand.

According to a further embodiment, at least a part of the area of said attachment device that will be in contact with said first hand when the attachment device is positioned as intended on said first hand comprises a padding of a material that is flexible and that is capable of being adapted to the shape of the corresponding part of said first hand of a person using the device. Also such a padding contributes to a secure attachment of the device onto the hand.

According to another embodiment of the invention, said U-shaped portion, at least in the area of said bent part, is at least slightly flexible, such that, by applying a small force, the first and second parts may be flexed apart to simplify the positioning of said device on the first hand, wherein, when said force is no longer applied, the first and second parts tend to move back by a spring action towards their rest position which they have when no force is applied. Such a design makes it easy to position the unit on a hand of a user.

According to a further embodiment, said U-shaped portion is designed such that the device may easily be slid onto a normal hand of a user of the device such that the first and second parts and the bent part reach the position of the first hand defined above and such that the device will be retained on said first hand by said spring action. By such a design, the unit is easy to attach to a hand and is held comfortably and securely fastened to the hand. It should be noted that instead of holding the device by said spring action it is possible to provide the device with some mechanical arrangement by means of which it is possible to apply a small force to said first and second parts such that these parts exert a small pressure on the hand in order to hold the device attached to the hand.

According to a further embodiment, when the first and second parts are in their rest position, the distance between the first and second parts close to the bent part is larger than the distance between said first and second parts at a location further away from said bent part. By this design, the first and second parts may securely hold the unit to the hand by the mentioned spring action.

According to another embodiment, said second part is at least slightly curved such that it has a convex shape as seen from the first part, such that the second part is adapted to the shape of the front portion of the hand where the second part is suited to be positioned. It should be noted that according to this embodiment it is not the case that necessarily the whole second part has a convex shape, it may be sufficient that a portion of the second part has a. convex shape in order to correspond to the shape of the hand.

According to a further embodiment, said first part is at least slightly curved such that it has a concave shape as seen from the second part, such that the first part is adapted to the shape of the back portion of the hand where the first part is suited to be positioned. Also according to this embodiment, it is possible that only a part of the first part has such a concave shape.

According to another embodiment, at least the surfaces of said first and second parts facing each other are formed with a surface pattern which allows air to reach the portions of said first hand where said first and second parts are positioned in order to allow for ventilation of said portions of the hand. The pattern is thus suitably such that air may reach the part of the hand located inside said first and second parts.

According to a further embodiment, each of said first and second parts has such a length as to extend at least substantially all the way across said first hand of a user when the device is attached as intended on said first hand. Since said parts are relatively long, it is possible to position more input members on said parts.

According to a further embodiment, the unit comprises a fixation member designed to connect the ends of said first and second parts, located furthest away from said bent part, to each other when the device is attached as intended on said first hand. Through this embodiment, the unit may be even more securely attached to the hand.

According to a further embodiment, the unit comprises a transmitter unit arranged for transmitting said signals to the peripheral unit in a wireless manner. This construction makes it easier to use the unit since no wire or cable has to be present. It should however be noted, that within the scope of the invention is also the possibility that the portable unit is connected to the peripheral unit by means of a cable.

According to a further embodiment, said first input member is permanently attached to said attachment device. According to this embodiment, the input member thus forms an integral part of the attachment device.

According to an alternative embodiment, said first input member is releasably connected to said attachment device such that the first input member may be easily removed from and connected to the attachment device. According to this embodiment, the input member or members may be positioned on a separate unit that can easily be attached and removed from the attachment device. This may be made possible, for example, by means of a snap-in fixation or by means of other quick attach and release mechanisms.

According to a further embodiment, the unit comprises at least a second input member arranged on said attachment device for inputting signals to said peripheral unit. By having several input members, different kinds of control signals may be transferred to the peripheral unit in an efficient manner.

According to a further embodiment, at least one of said input members is arranged for inputting signals to the peripheral unit in order to perform the same or a similar function as a joystick or as the movement of a standard computer mouse. It has been found to be comfortable and easy to use such an input member when this input member forms a part of a portable unit according to the invention.

According to another embodiment, at least one of said input members is positioned on said first part or on said bent part in such a position as to be easily operated by a finger of the second hand of the user when the device is positioned as intended on said first hand. Such a unit has been found to be particularly comfortable to use. In particular, it is preferred that said input member which is arranged for inputting signals to the peripheral unit in order to perform the same or a similar function as a joystick or as the movement of a standard computer mouse is positioned on said first part or on said bent part.

According to a still further embodiment, at least one of said input members is positioned on said second part or on said bent part in such a position as to be easily operated by a finger of the first hand of the user when the device is positioned as intended on said first hand. The fingers of the first hand may thus be used to operate one or more input members located on the unit on the first hand. It should be noted that this embodiment may of course be combined with the embodiment that also the first part has one or more input members. The portable unit may thus be operated by both hands at the same time.

According to a further embodiment, the unit comprises a plurality of input members positioned on said attachment device such that, when the device is positioned as intended on said first hand, they are easily operated with a plurality of fingers of the second hand when at least a majority of the fingers of said first hand are kept straight or folded and when at least a plurality of fingers of the second hand are held on top of said fingers of the first hand. Such a position of the input members has been found to be easy and comfortable to use.

According to a further embodiment, the unit comprises a plurality of input members positioned on said attachment device such that, when the device is positioned as intended on said first hand, they are easily operated with a plurality of fingers of the second hand when at least a majority of the fingers of said first hand are kept interlaced with fingers of the second hand. Also this arrangement of the input members has been found advantageous for a user.

The invention also concerns the use of the portable unit. According to the use of the unit, said device is attached to a first hand of the user in the position defined above. The advantage of such a use is clear from the above explanation in connection with the portable unit according to the invention. Further advantageous manners of using the device are clear from the remaining dependent use claims and from the description below.

### SHORT DESCRIPTION OF THE DRAWINGS

FIG. 1 shows a schematic example of a portable unit according to the invention attached to a hand of a user.

FIG. 2 shows schematically a cross-section of the hand with an attached unit in the section marked with A-A in FIG. 1.

FIG. 3 shows schematically a similar section as FIG. 2 of a U-shaped portion that forms part of the unit when the unit is not attached to a hand.

FIGS. 4 and 5 show schematically other examples of the design of at least a part of the unit according to the invention in cross-sections similar to that of FIGS. 2 and 3.

FIG. 6 illustrates a manner of using a portable unit according to the invention.

FIG. 7 illustrates another manner of using a portable unit according to the invention.

### DESCRIPTION OF EMBODIMENTS OF THE INVENTION

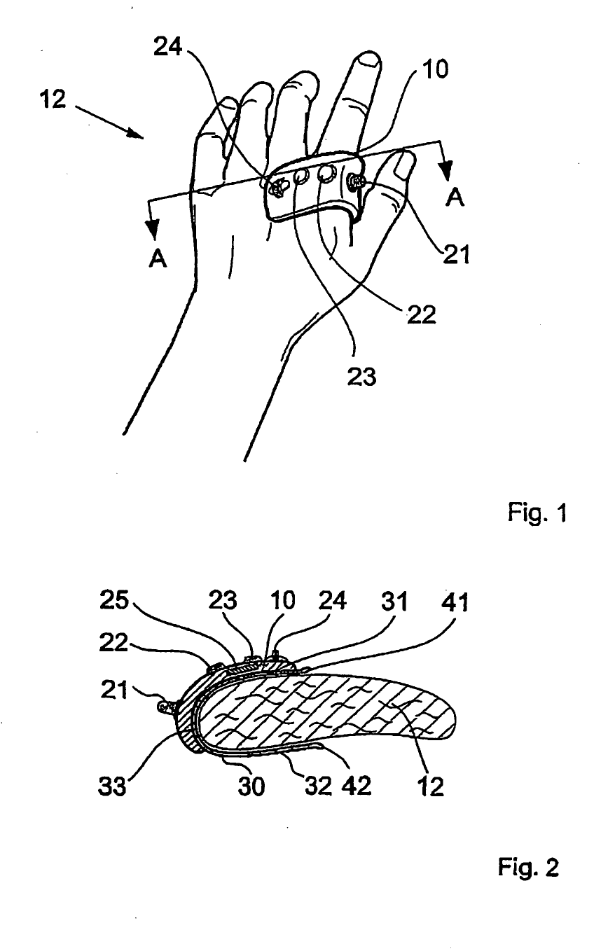

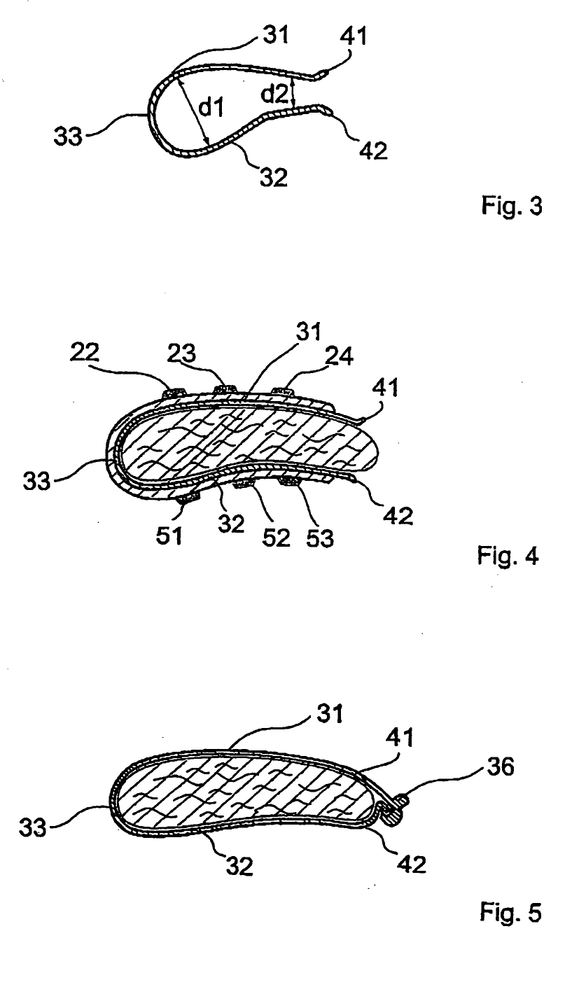

Embodiments of the invention will now be described with reference to the attached figures. For the sake of simplicity, the thumb of the first hand is not shown in the FIGS. 2, 4 and 5. Furthermore, on FIGS. 3 and 5 only a part of the portable unit according to the invention is shown, i.e. the U-shaped portion.

A portable unit according to the invention comprises a hand attachment device 10 and one or more input members 21-24, 51-53 arranged on the hand attachment device 10. The input members 21-24, 51-53 are preferably permanently attached to the attachment device 10. However, according to an alternative embodiment, it is also possible that the input members 21-24, 51-53 are connected to the attachment device 10 such that the input members may be quickly removed from and connected to the attachment device 10. The input members may in this case form part of a separate unit that is attached to the attachment device 10 via a quick coupling, such as a snap-in fixture or a similar arrangement. It should be noted that by “permanently attached” is here meant that the input members normally form part of the unit and cannot easily and quickly be removed therefrom.

The input members 21-24, 51-53 are arranged for inputting signals to a peripheral unit. This peripheral unit may be a computer which is thus fed with control signals generated by the portable unit. The input members 21-24, 51-53 may be arranged or programmed to for example generate alphanumeric characters on a screen which forms part of the peripheral unit. The input members 21-24, 51-53 may also be used to input other commands. For example, at least one input member 21 may be arranged for inputting signals to the peripheral unit in order to perform the same or a similar function as a joystick or as the movement of a standard computer mouse. The input member 21 may for example be designed as a small micro joystick. The input member 21 may also have the form of a ball or a plate arranged for capacitive or resistive sensing. According to an alternative embodiment (not shown), the first input member may comprise a camera arranged in the attachment device 10. The camera is arranged to sense the movement of for example a finger of the user across an opening or a camera window arranged in the attachment device 10 in order to perform the “mouse-function”. Such a portable unit with a camera may also be arranged to sense the fingerprint of the user in order to check the identity of the user and in order to check whether the user is entitled to have access to the portable unit or to the peripheral unit with which the portable unit communicates. Some of the input members 21-24, 51-53 may also be arranged or programmed to fulfil the function of the normal click-buttons on a computer mouse. Some input member 24 may be arranged to fulfil the function of a scroll-wheel. The number of input members 21-24, 51-53 may vary but preferably a plurality of input members 21-24, 51-53 are arranged on the attachment device 10.

The portable unit according to the invention may of course comprise suitable electronic parts for generating the signals and for communicating with the peripheral unit. The portable unit may be connected to the peripheral device by means of a cable but preferably the unit comprises a transmitter unit 25 arranged for transmitting the signals to the peripheral unit in a wireless manner. The communication may for example be via a radio link or an optical link. The device may also comprise a battery. The portable unit may also include a memory so that information may be inputted to the portable unit and stored in the memory instead of being directly transmitted to the peripheral unit.

The attachment device is designed such that it is easily attachable to and removable from a hand 12 of a person using the device. In the shown embodiment, the hand 12 is the left hand. However, the attachment device 10 could instead be arranged to be easily attachable to and removable from the right hand. The attachment device 10 comprises a U-shaped portion 30. The U-shaped portion 30 has first 31 and second 32 at least relatively straight parts and a bent part 33 connecting the first 31 and second 32 parts. The attachment device 10 is designed to be attachable to the hand 12 such that the first part 31 is located essentially on the back of the hand 12, the second part 32 is located essentially on the front of the hand 12 while the bent part 33 extends from the back of the hand 12 to the front of the hand 12 in the area between the thumb and the index finger of the hand 12.

The U-shaped portion 30 may be made such that the first 31 and second 32 parts are parallel to each. However, according to one advantageous embodiment (not shown), the U-shaped portion 30 is twisted, such that the first 31 and second 32 parts are not parallel to each other, but point in different directions.

The attachment device 10 does not need to be particularly flexible. The part of the attachment device 10 that will be in contact with said first hand 12 when the attachment device 10 is positioned as intended on said first hand 12 may be designed to have a form that at least substantially corresponds to the shape of a normally built hand 12 of a person using the device. Thereby the device will be maintained at the hand 12. At least a part of the attachment device 10 that will be in contact with the hand 12, when the attachment device 10 is positioned as intended on the hand 12, may comprises a padding of a material that is flexible and that is capable of being adapted to the shape of the corresponding part of the hand 12.

According to an alternative embodiment, the U-shaped portion 30 is made to be at least slightly flexible, at least in the area of the bent part 33. Thereby, the first 31 and second 32 parts may be flexed apart to simplify the positioning of the attachment device 10 onto the hand 12. FIG. 3 shows an example of a U-shaped portion 30 when the unit is not attached to the hand of a person. As can be seen in this figure, the distance d1 between the first 31 and second 32 parts close to the bent part 33 is larger than the distance d2 between the first 31 and the second 32 parts located further away from the bent part 33. The U-shaped portion 30 thus tends to flex the first 31 and second 32 parts back to the position shown in FIG. 3. This makes it possible to slide the attachment device 10 onto the hand 12 of a user of the device 10, whereby the first 31 and second 32 parts tend to move back to the rest position shown in FIG. 3, which means that the parts 31, 32 will tend to exert a small pressure on the hand 12 such that the attachment device 10 is retained on the hand 12 by this spring action. In order to simplify the positioning of the portable unit onto the hand 12, by said sliding motion, the ends 41, 42 of the first 31 and second 32 parts may be slightly curved away from each other. The U-shaped portion 30 may preferably be shaped according to the anatomy of the part of a normal hand of a person to which the attachment device 10 is to be attached. This means that the second part 32 may be slightly curved to have a convex shape as seen from the first part 31. The second part 32 is thus adapted to the shape of the front portion of the hand 12 where the second part 32 is meant to be positioned. Similarly, the first part 31 may be slightly curved such that it has a concave shape as seen from the second part 32. The first part 31 may thus be adapted to the shape of the back portion of the hand 12 where the first part 31 is meant to be positioned.

It should be noted that it is not necessary that the mentioned distance d1 is larger than d2. In particular in an embodiment when the U-shaped portion 30 is not made to be particularly flexible, the distance d2 can even be larger than d1.

In the shown embodiment the two parts 31 and 32 have substantially the same length. This is however not necessary. It is also possible that one of the parts 31, 32 is substantially longer than the other part. Furthermore, it is also possible that the attachment device 10 comprises further parts in addition to the U-shaped portion 30. The attachment device 10 may for example comprise an additional part (or parts) that protrudes out from the U-shaped portion and covers a larger part of, for example, the back of the hand in order to make room for more input members on the attachment device 10.

The surfaces of the attachment device 10 which are into contact with the hand 12 may preferably have a pattern which makes it possible for air to reach these parts of the hand. The unit is thereby more comfortable to wear. The attachment device 10 may, for example, be provided with a textile or cloth material on those parts of the device 10 which are in contact with the hand 12.

FIG. 2 shows a portable unit that has a relatively short extension across the hand 12. FIG. 4 shows an example where the first 31 and second 32 parts have such a length that they extend substantially all the way across the hand 12. This length makes it possible to include more input members 21-24, 51-53 on the attachment device 10.

FIG. 5 shows that the unit may comprise a fixation member 36 designed to connect the ends 41, 42 of the first 31 and second 32 parts. Thereby the unit may be securely fastened to the hand 12. Such a fixation member 36 may be formed in different manners.

The unit may have input members 21-24, 51-53 attached either to the front portion of the hand or to the back portion of the hand. FIG. 4 shows input members 22, 23, 24 on the back of the hand and input members 51, 52, 53 on the front side of the hand. The input members 22-24 are positioned such that they may be operated by the fingers of the right hand of the user when the device 10 is attached as intended onto the left hand 12. The input members 51-53 are positioned such that they may be operated by the fingers of the left hand when the device 10 is positioned as intended on this left hand 12. With this construction, the input members 51, 52, 53 may be operated by the fingers of the left hand while the input members 22, 23, 24 are operated by the fingers of the right hand. The portable unit may of course also include one or more input members positioned on the bent portion 33. FIG. 1 and FIG. 2 show one such input member 21.

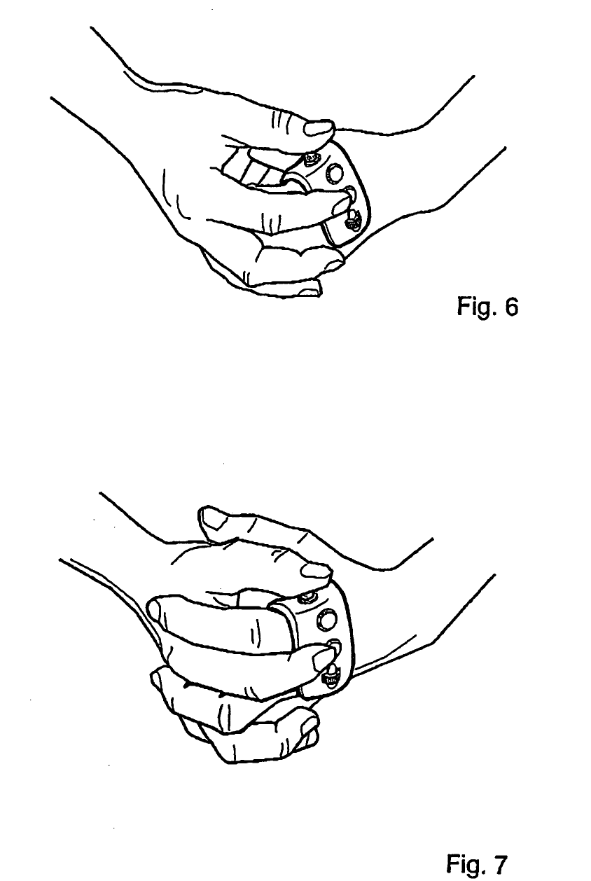

Preferably a plurality of input members 21-24 are positioned such that the portable unit may be used in the following manner (see FIG. 6) when it is attached to the left hand 12 as described above. The user holds at least a majority of the fingers of the left hand 12 folded and one or more fingers of the right hand are used to operate the input members 21-24 when the user holds at least a plurality of the fingers of the right hand on top of the folded fingers of the left hand 12. Alternatively, the unit could be used in the same manner except that the fingers of the first hand are kept straight.

According to another use of the portable unit (see FIG. 7), the user holds at least a majority of the fingers of the left hand 12 interlaced with fingers of the right hand. With the hands in this position one or more fingers of the right hand may be used to operate the input members 21-24. Additionally, the user may have a corresponding further portable unit attached to the second hand. In this case the user may operate input members on the portable units on both hands simultaneously.

Although the above embodiments primarily have been described with a portable unit designed to be worn on the left hand, the invention is equally applicable to a unit designed to be worn on the right hand.

The portably unit may be formed by any suitable material, such as a plastic material. The portable unit may of course comprise the necessary electronic parts for generating control signals. The input members 21-24, 51-53 may be formed in different manners, for example as mechanical keys or as touch-sensitive keys.

The U-shaped portion 30 may be made of the same material as and form a single unit with the rest of the attachment device 10. Alternatively, the U-shaped portion may be made separate from the rest of the attachment device 10 and fixed to the rest of the attachment device 10.

When in this document a hand or a normal hand is mentioned, it is primarily referred to a hand of a normal size of a grown-up person. The portable unit according to the invention could however be fabricated in different sizes for different hands.

The invention is not limited to the described embodiments but may be varied and modified within the scope of the following claims.

1-22. (Canceled)

23. A portable unit comprising a hand attachment device, suited to be easily attachable to and removable from a first hand of a person using the device, comprising; at least a first input member arranged on said hand attachment device for inputting signals to a peripheral unit which is not positioned on said attachment device, said attachment device including a U-shaped portion, having first and second at least relatively straight parts and a bent part connecting said first and second parts, said attachment device being designed to be attachable to said first hand such that the first part is located essentially on the back of the hand, the second part is located essentially on the front of the hand while the bent part extends from the back of the hand to the front of the hand in the area between the thumb and the index finger of said first hand, at least one of said input members being arranged for inputting signals to the peripheral unit in order to perform the same or a similar function as a joystick or as the movement of a standard computer mouse, and wherein said at least one of said input members, arranged for inputting signals to the peripheral unit in order to perform the same or a similar function as a joystick or as the movement of a standard computer mouse, is positioned on one of said first part and said bent part in such a position as to be easily operated by a finger of the second hand of the user when the device is positioned as intended on said first hand.

24. A portable unit according to claim 23, wherein said U-shaped portion is at least slightly twisted such that said first and second parts are not parallel to each other.

25. A portable unit according to claim 23, wherein at least a part of the area of said attachment device that will be in contact with said first hand when the attachment device is positioned as intended on said first hand has a form that at least substantially corresponds to the shape of the corresponding part of a normally built said first hand of a person using the device.

26. A portable unit according to claim 23, wherein at least a part of the area of said attachment device that will be in contact with said first hand when the attachment device is positioned as intended on said first hand comprises a padding of a material that is flexible and that is capable of being adapted to the shape of the corresponding part of said first hand of a person using the device.

27. A portable unit according to claim 23, wherein said U-shaped portion, at least in the area of said bent part, is at least slightly flexible, such that, by applying a small force, the first and second pats may be flexed apart to simplify the positioning of said device on the first hand, wherein, when said force is no longer applied, the first and second part tend to move back by a spring action towards their rest position which they have when no force is applied.

28. A portable unit according to claim 1, wherein said U-shaped portion is designed such that the device may easily be slid onto a normal hand of a user of the device such that the first and second parts and the bent part reach the position of the first hand defined in claim 1 and such, that the device will be retained on said first hand by said spring action.

29. A portable unit according to claim 27, wherein, when the first and second parts are in their rest position, the distance between the first and second parts close to the bent part is larger than the distance between said first and second parts at a location further away from said bent part.

30. A portable unit according to claim 23, wherein said second part is at least slightly curved such that it has a convex shape as seen from the first part, such that the second part is adapted to the shape of the front portion of the hand where the second part is suited to be positioned.

31. A portable unit according to claim 23, wherein said first part is at least slightly curved such that it has a concave shape as seen from the second part, such that the first part is adapted to the shape of the back portion of the hand where the first part is suited to be positioned.

32. A portable unit according to claim 23, wherein at least the surfaces of said first and second parts facing each other are formed with a surface pattern which allows air to reach the portions of said first hand where said first and second parts are positioned in order to allow for ventilation of said portions of the hand.

33. A portable unit according to claim 23, wherein each of said first and second parts has such a length as to extend at least substantially all the way across said first hand of a user when the device is attached as intended on said first hand.

34. A portable unit according to claim 33, comprising a fixation member designed to connect the ends of said first and second parts, located furthest away from said bent part, to each other when the device is attached as intended on said first hand.

35. A portable unit according to claim 23, comprising a transmitter unit arranged for transmitting said signals to the peripheral unit in a wireless manner.

36. A portable unit according to claim 23, wherein said first input member is permanently attached to said attachment device.

37. A portable unit according to claim 23, wherein said first input member is releasably connected to said attachment device such that the first input member may be easily removed from and connected to the attachment device.

38. A portable unit according to claim 23, comprising at least a second input member arranged on said attachment device for inputting signals to said peripheral unit.

39. A portable unit according to claim 23, wherein at least one of said input members is positioned on said second part or on said bent part in such a position as to be easily operated by a finger of the first hand of the user when the device is positioned as intended on said first hand.

40. A portable unit according to claim 23, comprising a plurality of input members positioned on said attachment device such that, when the device is positioned as intended on said first hand, they are easily operated with a plurality of fingers of the second hand when at least a majority of the fingers of said first hand are kept straight or folded and when at least a plurality of fingers of the second hand are held on top of said fingers of the first hand.

41. A portable unit according to claim 23, comprising a plurality of input members positioned on said attachment device such that, when the device is positioned as intended on said first hand, they are easily operated with a plurality of fingers of the second hand when at least a majority of the fingers of said first hand are kept interlaced with fingers of the second hand.

42. A portable unit according to claim 23, wherein said device is attached to a first hand of the user.

43. A portable unit according to claim 42, wherein at least a majority of the fingers of said first hand are kept straight or folded and wherein at least one finger of the second hand of the user is used to operate said first input member and wherein at least a plurality of fingers of the second hand are held on top of said fingers of the first hand.

44. A portable unit according to claim 42, wherein at least a majority of the fingers of said first hand are kept interlaced with fingers of the second hand and wherein at least one finger of said second hand is used to operate said first input member.
